(19) United States
(12) Patent Application Publication
(10) Pub. No.: US 2025/0151548 A1
(43) Pub. Date: May 8, 2025

(54) DISPLAY DEVICE AND DISPLAY PANEL

(71) Applicant: LG Display Co., Ltd., Seoul (KR)

(72) Inventors: SeungJae BAEK, Paju-si (KR); Youngbae KIM, Paju-si (KR)

(73) Assignee: LG Display Co., Ltd., Seoul (KR)

(21) Appl. No.: 18/793,618

(22) Filed: Aug. 2, 2024

(30) Foreign Application Priority Data
Nov. 3, 2023 (KR) 10-2023-0150545

(51) Int. Cl. H10K 59/131; H10K 59/40; H10K 59/80

(52) U.S. Cl. CPC H10K 59/131; H10K 59/873; H10K 59/40

(57) ABSTRACT

Discussed are a display device and a display panel. The display device includes a display panel having a plurality of subpixels and at least one driving circuit configured to drive the display panel. In the display panel, a circuit layer is disposed on the substrate, signal lines are disposed on the circuit layer and electrically connected to a circuit film on which the driving circuit is mounted, and a light-emitting element layer is disposed to overlap at least a portion of the signal lines and the circuit film. Further, in the display panel, a polarizing film is disposed on the light-emitting element layer and disposed to overlap at least a portion of the circuit film, an adhesive layer covers sides of the polarizing film, the light-emitting element layer, and the circuit layer, and a cover window is disposed on the polarizing film.

### CROSS-REFERENCE TO RELATED APPLICATION

This application claims priority to Korean Patent Application No. 10-2023-0150545, filed in the Republic of Korea on Nov. 3, 2023, the entire contents of which is hereby expressly incorporated by reference into the present application.

### BACKGROUND

### Field

Embodiments of the present disclosure relate to a display device and a display panel and, more particularly, to a display device and a display panel having a structure capable of reducing defects or failures which can be caused by static electricity introduced to a bezel area of the display panel.

### Discussion of the Related Art

In display devices that display images using digital data, liquid crystal display (LCD) devices using liquid crystals, organic light-emitting display devices using organic light-emitting diodes (OLED), and the like are representative examples.

Among such display devices, organic light-emitting display devices are advantageous in terms of rapid response rates, high contrast ratios, high emission efficiency, high luminance, wide viewing angles, and the like, since light-emitting diodes emitting light by themselves are used therein. In this case, the light-emitting diodes can be made of an inorganic material or an organic material.

Such an organic light-emitting display device can include light-emitting diodes disposed in a plurality of subpixels arrayed in a display panel, and can control the light-emitting diodes to emit light by controlling a voltage flowing through the light-emitting diodes, thereby displaying an image while controlling the luminance of the respective subpixels.

Recently, the range of use of such display devices has been expanded to include portable computers as well as desktop computer monitors, smartphones, wall-mounted televisions, and the like. In addition, in terms of the design of display devices, thinner display panels each having thinner edges are increasingly favored.

In this case, as the bezel of the display panel becomes thinner, wiring or circuitry disposed on a board can be exposed externally, and defects or poor signals can be caused by static electricity or the like flowing through the bezel.

### SUMMARY OF THE DISCLOSURE

Accordingly, the inventors of the present disclosure have invented a display device and a display panel having a structure capable of reducing defects or failures which can be caused by introduced static electricity.

Embodiments of the present disclosure can provide a display device and a display panel in which signal lines or probing pads disposed on a bezel can be covered from above by extending a polarizing film, thereby reducing defects or failures.

Furthermore, embodiments of the present disclosure can provide a display device and a display panel in which, pads can be formed on the bezel and then a polarizing film can be attached on the top of the pad, thereby reducing defects or failures which can be caused by static electricity introduced to signal lines or probing pads disposed on the bezel.

Embodiments of the present disclosure can provide a display device including a display panel having a plurality of subpixels, and at least one driving circuit driving the display panel, wherein the display panel includes a substrate, a circuit layer disposed on the substrate, signal lines disposed on the circuit layer and electrically connected to a circuit film on which the driving circuit is mounted, a light-emitting element layer disposed to overlap at least a portion of the signal lines and the circuit film, a polarizing film disposed on the light-emitting element layer and disposed to overlap at least a portion of the circuit film, an adhesive layer covering sides of the polarizing film, the light-emitting element layer, and the circuit layer, and a cover window disposed on the polarizing film.

Embodiments of the present disclosure can provide a display panel including a substrate, a circuit layer disposed on the substrate, signal lines disposed on the circuit layer and electrically connected to a circuit film on which a driving circuit is mounted, a light-emitting element layer disposed to overlap at least a portion of the signal lines and the circuit film, a polarizing film disposed on the light-emitting element layer and disposed to overlap at least a portion of the circuit film, an adhesive layer covering sides of the polarizing film, the light-emitting element layer, and the circuit layer, and a cover window disposed on the polarizing film.

According to embodiments of the present disclosure, defects or failures in the display device which can be caused by static electricity introduced can be reduced or eliminated.

In addition, according to embodiments of the present disclosure, the signal lines or the probing pads disposed on a bezel can be covered from above by extending the polarizing film, thereby reducing or minimizing defects or failures in the display device.

Furthermore, according to embodiments of the present disclosure, by forming pads on the bezel and attaching the polarizing film on the top of the pads, process optimization for reducing or minimizing defects or failures which can be caused by static electricity introduced to the signal lines or the probing pads disposed on the bezel can be realized.

### BRIEF DESCRIPTION OF THE DRAWINGS

The above and other objectives, features, and advantages of the present disclosure will be more clearly understood from the following detailed description, taken in conjunction with the accompanying drawings, in which:

FIG. 1 illustrates a schematic configuration of a display device according to embodiments of the present disclosure;

FIG. 2 illustrates an example touch sensing system of the display device according to embodiments of the present disclosure;

FIG. 3 illustrates an example structure by which a touchscreen panel is disposed inside a display panel in the display device according to embodiments of the present disclosure;

FIG. 4 illustrates an arrangement of pads and signal lines in a non-display area of the display device according to embodiments of the present disclosure;

FIG. 5 is a cross-sectional view illustrating a situation in which static electricity is introduced to a data line connected to a circuit film;

FIG. 6 is a cross-sectional view illustrating a situation in which static electricity is introduced to a probing pad located on an outside of the circuit film;

FIGS. 7 to 15 are cross-sectional views sequentially illustrating a process of manufacturing a display device according to embodiments of the present disclosure;

FIG. 16 illustrates an arrangement of a polarizing film in a non-display area of the display device according to embodiments of the present disclosure; and

FIGS. 17A and 17B are cross-sectional views illustrating an example in which the polarizing film blocks static electricity introduced from the outside.

### DETAILED DESCRIPTION OF THE EMBODIMENTS

Hereinafter, some embodiments of the present disclosure will be described in detail with reference to exemplary drawings. In the following description of examples or embodiments of the present invention, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description can make the subject matter in some embodiments of the present invention rather unclear. The terms such as “including”, “having”, “containing”, “constituting”, “made up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the present invention. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

In describing a positional relationship where the positional relationship between two parts is described, for example, using “on,” “over,” “above,” “under,” “below,” “beneath,” “near,” “close to,” “adjacent to,” “beside,” “next to,” or the like, one or more other parts can be located between the two parts unless a more limiting term, such as “immediate(ly),” “direct(ly),” or “close(ly),” is used. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference, unless otherwise specified.

When time relative terms, such as “after”, “subsequent to”, “next”, “before”, and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may”.

Hereinafter, various embodiments of the present disclosure will be described in detail with reference to the accompanying drawings. All the components of each display device or each display panel according to all embodiments of the present disclosure are operatively coupled and configured.

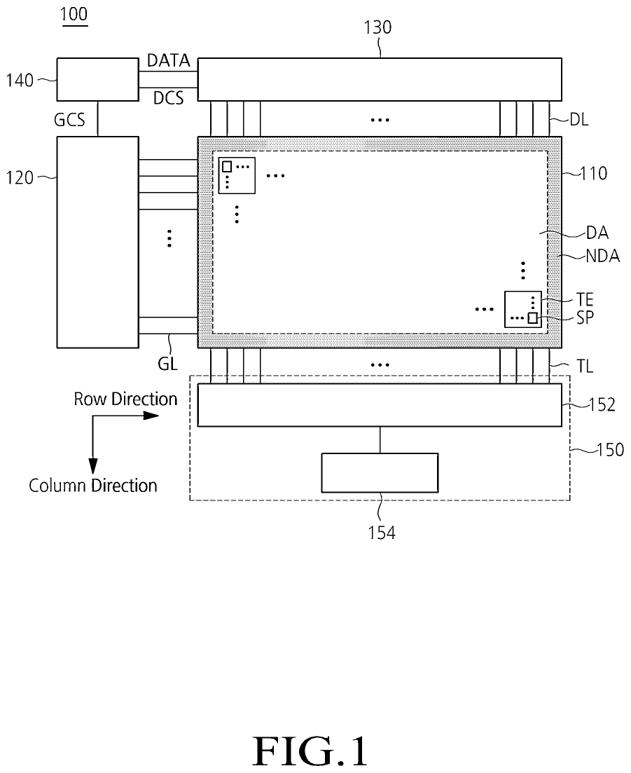

FIG. 1 illustrates a schematic configuration of a display device according to embodiments of the present disclosure.

Referring to FIG. 1, a display device 100 according to embodiments of the present disclosure can include a display panel 110, a gate driving circuit 120, a data driving circuit 130, and a timing controller 140 as components for displaying images.

The display panel 110 can include a display area DA in which images are displayed and a non-display area NDA in which no images are displayed.

The non-display area NDA can be an area outside the display area DA, and can also be referred to as a bezel. The non-display area NDA can be an area that is visible in front of the display device 100, or can be an area that is bent so as not to be visible in front of the display device 100. The non-display area NDA can surround the display area DA entirely or in part.

The display panel 110 can include a plurality of subpixels SP. Each of the subpixels SP can have different structures depending on the type of display device 100. For example, when the display device 100 is a self-emitting display device in which the subpixels SP are self-emitting, each subpixel SP can include a self-emitting light-emitting element, one or more transistors, and one or more capacitors.

In addition, the display panel 110 can further include various types of signal lines to drive the subpixels SP. For example, the various types of signal lines can include a plurality of data lines DL transmitting data signals (also referred to as data voltages or image data) and a plurality of gate lines GL carrying gate signals (which can include scanning signals, sensing signals, or light-emitting signals).

The data lines DL can intersect the gate lines GL. The respective data lines DL can be arranged to extend in a column direction. The respective gate lines GL can be arranged to extend in a row direction.

Here, the column direction and the row direction are relative. For example, the column direction can be a vertical direction and the row direction can be a horizontal direction. In another example, the column direction can be a horizontal direction and the row direction can be a vertical direction.

The data driving circuit 130 is a circuit for driving the data lines DL, and can output data signals to the data lines DL. The gate driving circuit 120 is a circuit for driving the gate lines GL, and can output gate signals to the gate lines GL.

The timing controller 140 is a device for controlling the data driving circuit 130 and the gate driving circuit 120, and can control driving timing for the data lines DL and driving timing for the gate lines GL.

The timing controller 140 can supply various types of data drive control signals DCS to the data driving circuit 130 to control the data driving circuit 130 and various types of gate drive control signals GCS to the gate driving circuit 120 to control the gate driving circuit 120.

The gate driving circuit 120 can supply gate signals to the gate lines GL in response to the timing control of the timing controller 140. The gate driving circuit 120 can be supplied with a first gate voltage corresponding to a turn-on level voltage and a second gate voltage corresponding to a turn-off level voltage along with various gate drive control signals GCS, generate gate signals, and supply the same to the gate lines GL. Here, the turn-on level voltage can be a high level voltage and the turn-off level voltage can be a low level voltage. Conversely, the turn-on level voltage can be a low level voltage and the turn-off level voltage can be a high level voltage.

The data driving circuit 130 can supply data signals to the data lines DL in response to driving timing control of the timing controller 140. The data driving circuit 130 can receive digital image data DATA from the timing controller 140, convert the received image data DATA into analog data voltages, and output the same to the data lines DL.

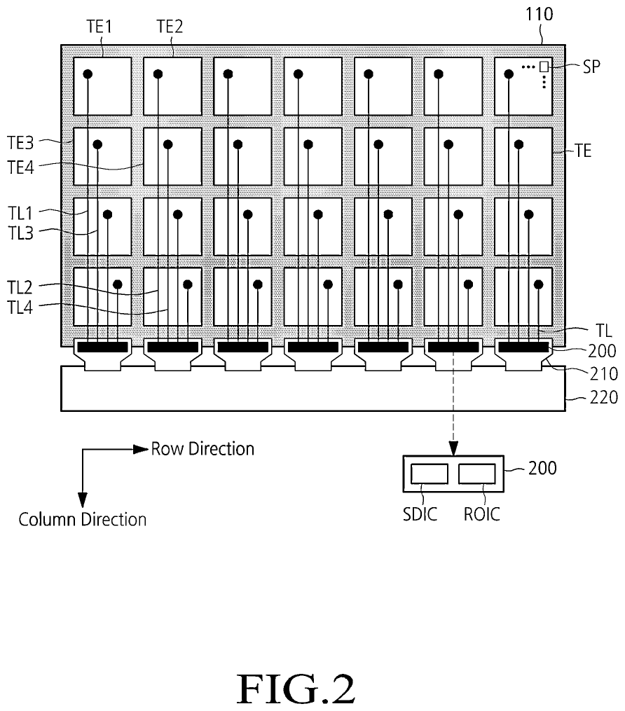

The data driving circuit 130 can include a plurality of data driving integrated circuits SDIC (see FIG. 2).

To provide not only an image display function but also a touch sensing function, the display device 100 can include a touchscreen panel and a touch circuit 150 that senses the touchscreen panel to detect whether a touch has been made by a touch object, such as a finger or a pen (e.g., a stylus), or to detect a touch position.

The touch circuitry 150 can include a touch driving circuit 152 to drive and sense the touchscreen panel to generate touch sensing data, a touch controller 154 to detect a touch event or a touch position using the touch sensing data, and the like.

The touchscreen panel can include a plurality of touch electrodes TE as touch sensors. The touchscreen panel can further include a plurality of touch lines TL for electrically connecting the touch electrodes TE to the touch driving circuit 152. The touchscreen panel or touch electrodes TE can also be referred to as touch sensors.

The touchscreen panel can be present external to the display panel 110 or internal to the display panel 110. When the touchscreen panel is external to the display panel 110, the touchscreen panel is referred to as an external touchscreen panel. When the touchscreen panel is external, the touchscreen panel and the display panel 110 can be fabricated separately and sequentially coupled. The external touchscreen panel can include a substrate and the touch electrodes TE over the substrate.

When the touchscreen panel is present internal to the display panel 110, the touchscreen panel is referred to as an in-cell touchscreen panel. When the touchscreen panel is an in-cell touchscreen panel, the touchscreen panel can be provided within the display panel 110 during the fabrication process of the display panel 110.

The touch driving circuit 152 can supply a touch driving signal to at least one of the touch electrodes TE, and can detect a touch sensing signal transmitted from at least one of the touch electrodes TE to generate touch sensing data.

The touch driving circuit 152 can include a plurality of touch driving integrated circuits ROIC (see FIG. 2).

The touch circuit 150 can perform touch sensing in a self-capacitance touch sensing manner or a mutual capacitance touch sensing manner.

When the touch circuit 150 performs touch sensing in the self-capacitance sensing manner, the touch circuit 150 can perform touch sensing based on the capacitance between each touch electrode TE and a touch object (e.g., a finger, a pen, etc.).

When the touch circuit 150 performs touch sensing in the mutual capacitance sensing manner, the touch circuit 150 can perform touch sensing based on the capacitance between the touch electrodes TE.

According to the mutual capacitance sensing method, the touch electrodes TE are divided into touch driving electrodes and touch sensing electrodes. The touch driving circuit 152 can drive each touch driving electrode using a touch driving signal and detect a touch sensing signal from each touch sensing electrode.

According to the self-capacitance sensing method, each of the touch electrodes TE can act as a touch driving electrode and as a touch sensing electrode. The touch driving circuit 152 can drive all or some of the touch electrodes TE and sense all or some of the touch electrodes TE.

The touch driving circuit 152 and the touch controller 154 can be implemented as separate devices or as a single device.

The touch driving circuit 152 and the data driving circuit 130 can each be implemented as an integrated circuit. In another example, the entirety or a portion of the touch driving circuit 152 and the entirety or a portion of the data driving circuit 130 can be integrated with each other to form a single integrated circuit.

FIG. 2 illustrates an example touch sensing system of the display device according to embodiments of the present disclosure.

Referring to FIG. 2, the touch sensing system of the display device 100 according to embodiments of the present disclosure can include a plurality of touch electrodes TE, a plurality of touch lines TL, a touch driving circuit 152, a touch controller 154, and the like.

In the display device 100 according to embodiments of the present disclosure, the data driving circuit 130 can include a plurality of data driving integrated circuits SDIC, and the touch driving circuit 152 can include a plurality of touch driving integrated circuits ROIC.

Each of the data driving integrated circuits SDIC can be implemented as a separate integrated circuit. Each of the touch driving integrated circuits ROIC can be implemented as a separate integrated circuit.

In another example, at least one data driving integrated circuit SDIC and the at least one touch driving integrated circuit ROIC can be integrated with each other to form a single integrated circuit 200.

Accordingly, the display device 100 according to embodiments of the present disclosure can include one or more integrated circuits 200, each of which can include at least one data driving integrated circuit SDIC and at least one touch driving integrated circuit ROIC.

For example, in the display device 100 according to embodiments of the present disclosure, a plurality of integrated circuits 200 can be mounted over a plurality of circuit films 210, respectively. First sides of the circuit films 210 on which the integrated circuits 200 are mounted can be electrically connected to the display panel 110.

The other sides of the circuit films 210 on which the integrated circuits 200 are mounted can be electrically connected to a printed circuit board (PCB) 220.

In the display device 100 according to embodiments of the present disclosure, each of the touch electrodes TE can be electrically connected to the corresponding touch driving integrated circuit ROIC through at least one touch line TL.

All of the touch electrodes TE can be located on the same layer, and the touch lines TL can be located on a layer other than the layer on which the touch electrodes TE are located.

The touch electrodes TE can include a first touch electrode TE1, a second touch electrode TE2 adjacent to the first touch electrode TE1 in a row direction, a third touch electrode TE3 adjacent to the first touch electrode TE1 in a column direction, and a fourth touch electrode TE4 adjacent to the third touch electrode TE3 in the row direction.

The first touch electrode TE1 can be electrically connected to the first touch line TL1, the second touch electrode TE2 can be electrically connected to the second touch line TL2, the third touch electrode TE3 can be electrically connected to the third touch line TL3, and the fourth touch electrode TE4 can be electrically connected to the fourth touch line TL4.

The first touch line TL1 overlaps the third touch electrode TE3 but is not electrically connected to the third touch electrode TE3. The second touch line TL2 overlaps the fourth touch electrode TE4 but is not electrically connected to the fourth touch electrode TE4.

Each of the touch electrodes TE can overlap one or more subpixels SP.

For example, a single touch electrode TE can overlap two or more subpixels SP. For example, the area size of a single touch electrode TE can correspond to the area size of two or more subpixels SP. In this case, each of the touch electrodes TE can overlap two or more data lines DL, and can overlap two or more gate lines GL.

The first touch electrode TE1 and the second touch electrode TE2 are disposed in the same touch electrode row and therefore can overlap the same two or more gate lines GL. The third touch electrode TE3 and the fourth touch electrode TE4 are disposed in the same touch electrode row and therefore can overlap the same two or more gate lines GL.

The first touch electrode TE1 and the third touch electrode TE3 are disposed in the same touch electrode column and therefore can overlap the same two or more data lines DL. The second touch electrode TE2 and the fourth touch electrode TE4 are disposed in the same touch electrode column and therefore can overlap the same two or more data lines DL.

Each of the touch electrodes TE can be a mesh type electrode having a plurality of openings. Each of the openings in each touch electrode TE can correspond to emitting areas of subpixels SP, or can correspond to transmission areas (or transparent areas).

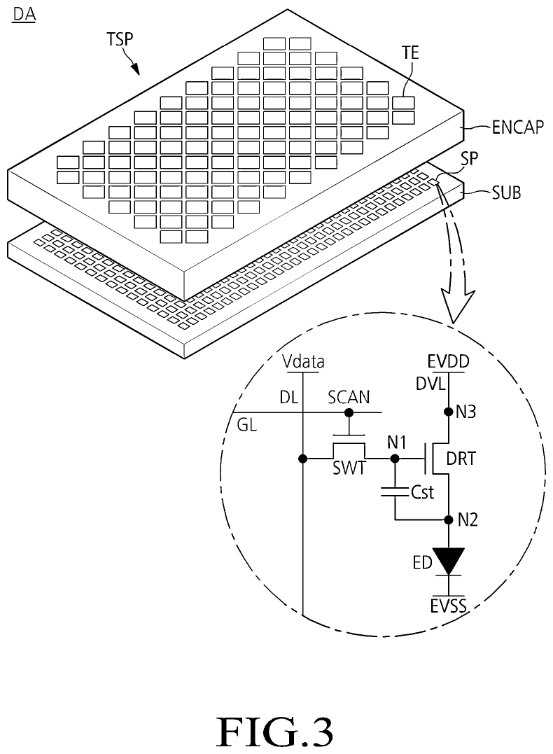

FIG. 3 illustrates an example structure by which a touchscreen panel is disposed inside a display panel in the display device according to embodiments of the present disclosure.

Referring to FIG. 3, in the display device 100 according to embodiments of the present disclosure, a display area DA of the display panel 110 has a plurality of subpixels SP arranged over a substrate SUB.

Each the subpixels SP can include a light-emitting element ED, a driving transistor DRT to drive the light-emitting element ED, a switching transistor SWT to transmit a data voltage Vdata to a first node N1 of the driving transistor DRT, and a storage capacitor Cst to maintain a constant voltage during a single frame.

The driving transistor DRT can include the first node N1 to which the data voltage Vdata is supplied through the switching transistor SWT, a second node N2 electrically connected to the light-emitting element ED, and a third node N3 to which a driving voltage EVDD is supplied from a driving voltage line DVL. The first node N1 can be a gate electrode of the driving transistor DRT, the second node N2 can be a source electrode of the driving transistor DRT, and the third node N3 can be a drain electrode of the driving transistor DRT.

The light-emitting element ED can include an anode, an emission layer, and a cathode. The anode can be electrically connected to the second node N2 of the driving transistor DRT, and a base voltage EVSS can be supplied to the cathode.

In such a light-emitting element ED, the emission layer can be an organic emission layer including an organic material. In this case, the light-emitting element ED can be an organic light-emitting diode (OLED).

The switching transistor SWT is on-off controlled by a scanning signal SCAN supplied through a gate line GL, and can be electrically connected to the first node N1 of the driving transistor DRT and to a data line DL.

When the switching transistor SWT is turned on by the scanning signal SCAN, the data voltage Vdata supplied through the data line DL is transmitted to the first node N1 of the driving transistor DRT.

The storage capacitor Cst can be electrically connected to the first node N1 and the second node N2 of the driving transistor DRT.

Each of the subpixels SP can have a 2T1C structure including two transistors DRT and SWT and a single capacitor Cst, and in some cases, can include one or more transistors or one or more capacitors.

The storage capacitor Cst can be an external capacitor intentionally designed to be provided external to the driving transistor DRT, rather than a parasitic capacitor, i.e., an internal capacitor that can be present between the first node N1 and the second node N2 of the driving transistor DRT.

The driving transistor DRT and the switching transistor SWT can each be an n-type transistor or a p-type transistor.

In addition, circuit elements, such as the light-emitting element ED, the two or more transistors DRT and SWT, and the one or more capacitors Cst, are provided in the display panel 110. Because these circuit elements are susceptible to external moisture, oxygen, and the like, an encapsulation layer ENCAP can be provided in the display panel 110 to prevent external moisture or oxygen from entering the circuit elements.

In the display device 100 according to embodiments of the present disclosure, a touchscreen panel TSP can be provided over the encapsulation layer ENCAP and be disposed inside the display panel 110. For example, in the display device 100, a plurality of touch electrodes TE of the touchscreen panel TSP can be disposed over the encapsulation layer ENCAP to form the display panel 110.

In this case, when the encapsulation layer ENCAP includes a plurality of layers, the touch electrode TE can be disposed between a first layer and a second layer among the plurality of encapsulation layers.

In a capacitance based touch sensing method, the display device 100 can sense a touch based on a mutual capacitance or can sense a touch based on a self-capacitance.

In the mutual capacitance based touch sensing method, a plurality of touch electrodes TE can be categorized into touch driving electrodes to which touch driving signals are supplied through touch driving lines and touch sensing electrodes on which touch sensing signals are sensed through touch sensing lines and form a capacitance with a touch driving electrode. In this case, the touch driving lines and the touch sensing lines can be collectively referred to as touch lines, and the touch driving signals and the touch sensing signals can be collectively referred to as touch signals.

In this case, the area of the touch driving electrodes for receiving the touch driving signals and the area of the touch sensing electrodes for transmitting the touch sensing signals can be the same or different.

For example, when it is desired to relatively reduce the parasitic capacitance generated by the touch sensing electrodes on which the touch sensing signals are sensed, the area of the touch sensing electrodes can be set to be smaller than the area of the touch driving electrodes. In this case, the area of the touch driving electrodes to which the touch driving signals are supplied and the area of the touch sensing electrodes on which the touch sensing signal are sensed can be in a ratio of from 5:1 to 2:1. In an example, the area of the touch driving electrodes and the area of the touch sensing electrodes can be in a ratio of 4:1.

Such a mutual capacitance based touch sensing method detects a touch, if any, and determines touch coordinates based on a change in mutual capacitance between the touch driving electrodes and the touch sensing electrodes depending on the presence or absence of a pointer, such as a finger or a pen.

In the self-capacitance based touch sensing method, each of the touch electrodes TE acts as both a touch driving electrode and a touch sensing electrode. For example, a touch driving signal is supplied to the touch electrode TE through one touch line, and a touch sensing signal transmitted from the touch electrode TE to which the touch driving signal is supplied is received through the same touch line. Accordingly, the self-capacitance based touch sensing method does not distinguish between a touch driving electrode and a touch sensing electrode or between a touch driving line and a touch sensing line.

In the self-capacitance based touch sensing method, the presence or absence of a touch and touch coordinates are detected and determined based on a change in capacitance between the pointer such, as a finger or a pen, and the touch electrode TE.

As such, the display device 100 can detect a touch using the mutual capacitance based touch sensing method or the self-capacitance based touch sensing method.

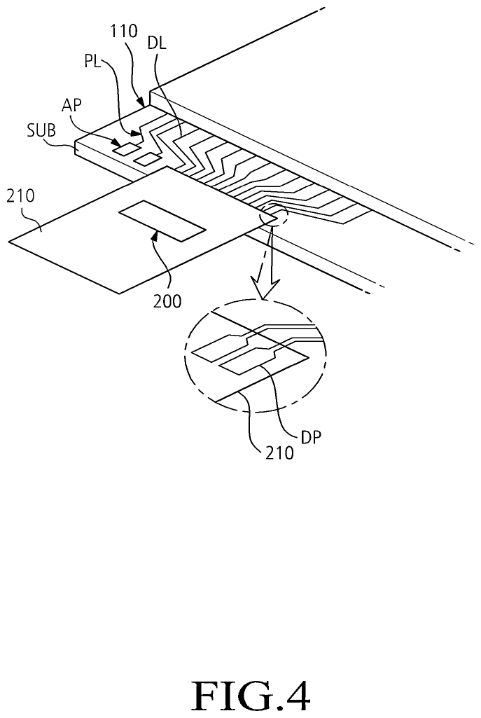

FIG. 4 illustrates an arrangement of pads and signal lines in a non-display area of the display device according to embodiments of the present disclosure.

Referring to FIG. 4, an inspection process for the display device 100 according to embodiments of the present disclosure can include an inspection of a driving circuit including the gate driving circuit 120, the date driving circuit 130, or the touch circuit 150, an inspection of signal lines such as data lines DL and gate lines GL provided on the substrate SUB, a subpixel inspection after subpixels are formed, an electrical inspection performed after the substrate SUB is bonded, an inspection of a light-emitting operation, and the like.

A repair process is a process of fixing defects found in the inspection process.

An automatic probe inspection can include an emission inspection performed on the substrate of the display panel 110 prior to mounting the driving circuit to inspect for defects in signal lines or thin film patterns over the substrate.

To enable the automatic probe inspection, probing pads AP to be contacted by a needle of an automatic probe inspection device and inspection lines PL connected to the probing pads AP are provided on the substrate SUB.

The probing pads AP can be disposed on an outside of the circuit film 210 on which the integrated circuit 200 is mounted.

In this case, the data lines DL for supplying a data voltage to the display panel 110 can be connected to the integrated circuit 200 through the data pads DP provided on the edge of the circuit film 210.

Because the data lines DL extend from the circuit film 210 to the display panel 110, the inspection lines PL can extend from the probing pads AP located on an outside of the circuit film 210 and extend outside the data lines DL.

The inspection lines PL connected to the probing pads AP can extend along the non-display area of the display panel 110 and be connected to switching elements located outside the display area.

In this case, because the probing pads AP and the data lines DL provided over the substrate SUB are located on a bezel of the display panel 110, the probing pads AP and the data lines DL may not be properly protected from external static electricity or the like in the process of realizing a narrow bezel.

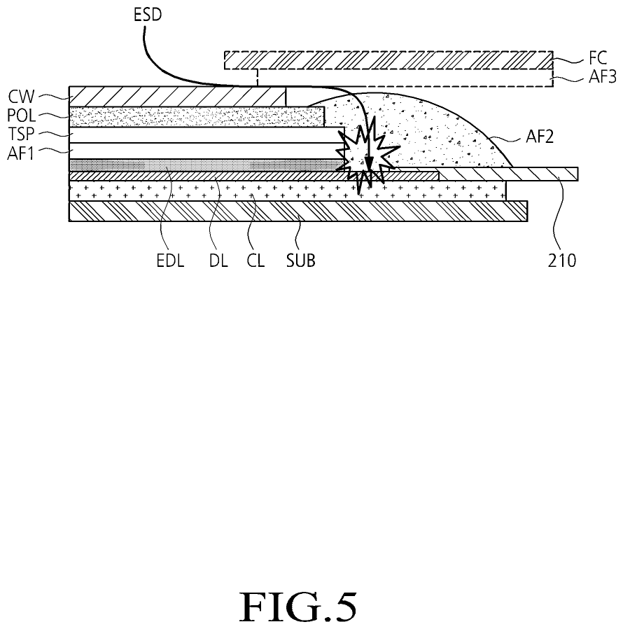

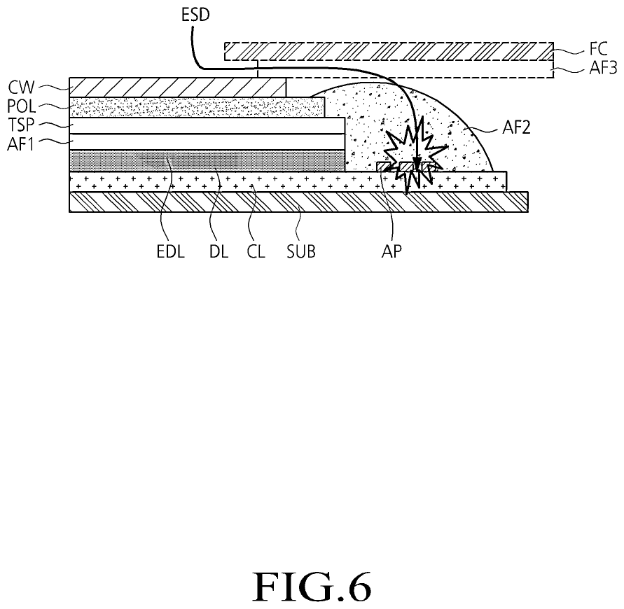

FIG. 5 is a cross-sectional view illustrating a situation in which static electricity is introduced to a data line connected to a circuit film, and FIG. 6 is a cross-sectional view illustrating a situation in which static electricity is introduced to a probing pad located on an outside of the circuit film.

Referring to FIGS. 5 and 6, the display device 100 can include a substrate SUB, a circuit layer CL on which transistors and the like are provided, a data line DL, a circuit film 210, a light-emitting element layer EDL, a first adhesive layer AF1, a touchscreen panel TSP, a polarizing film POL, and a cover window CW.

The substrate SUB can be formed of a transparent material such as glass, and a circuit layer CL including a driving transistor and a switching transistor can be provided on the top portion of the substrate SUB.

Signal lines, such as the data line DL through which data voltages are transmitted, can be provided on over the circuit layer CL. Only the data line DL connected to the circuit film 210 is shown here.

The light-emitting element layer EDL can be disposed over the signal lines such as the data line DL.

When the light-emitting element ED is implemented as an organic light-emitting diode, the light-emitting element layer EDL can include an anode, an emission layer, and a cathode. The emission layer can include a hole injecting layer (HIL), a hole transporting layer (HTL), an emitting material layer (EML), an electron transporting layer (ETL), and an electron injecting layer (EIL).

The first adhesive layer AF1 bonds the light-emitting element layer EDL thereunder and the touchscreen panel TSP thereon. When the display device 100 is not provided with a touch function, the touchscreen panel TSP can be omitted.

The first adhesive layer AF1 can be implemented as an optically clear adhesive (OCA) specifically manufactured for optically transparent bonding.

In this case, when the first adhesive layer AF1 is made of an optically clear adhesive, the first adhesive layer AF1 can have hyper elastic properties and can desirably have a low modulus of elasticity to absorb the stresses of the display panel 110. For example, the first adhesive layer AF1 can have an elastic modulus of 10 to 100 MPa.

In addition, the first adhesive layer AF1 can have a high strain rate to absorb stress due to bending of the display panel 110.

In general, materials such as metals exhibit a strain of about 10% to about 100% and rubber materials exhibit a large strain of 100% to 700%, but the strain of the first adhesive layer AF1 provided in the bending region of the display device 100 can have a value between 150% and 500%.

To achieve this performance, the first adhesive layer AF1 can be made of an acrylic resin, a poly(methacrylate) resin, a vinyl resin, a styrene resin, an ester resin, a rubber resin, an epoxy resin, a polyimide resin, a polyamide resin, a phenoxy resin, a polyurethane resin, or the like.

The polarizing film POL is provided over the touchscreen panel TSP to cover the display area.

The polarizing film POL can be in contact with a second adhesive layer AF2 provided on a side of the display panel 110 to reduce reflection of light entering from the outside. Specifically, when the display device 100 is used outside, external light can be introduced to be reflected by the anode or the cathode of the light-emitting element or reflected by metal electrodes disposed on the bottom of the light-emitting element. In this case, the reflected light can cause an image of the display device 100 to be difficult to visually recognized by a user.

The polarizing film POL polarizes light introduced from the outside in a specific direction and prevents light reflected by the anode electrodes or metal electrodes from being discharged back outside the display device 100.

The cover window CW can be disposed over the polarizing film POL. The cover window CW can be made of a transparent plastic material, a glass material, or a tempered glass material. In an example, the cover window CW can be one of a sapphire glass, a Gorilla Glass, or a multiple-layer (or multilayer) structure thereof. In another example, the cover window CW can include one material selected from polyethylene terephthalate (PET), polycarbonate (PC), polyether sulfone (PES), or polyethylenenaphthalate (PEN). The cover window CW can be made of tempered glass for scratch resistance and transparency.

The cover window CW can be bonded to the front cover FC through a third adhesive layer AF3. The front cover FC is disposed over the circuit film 210 to cover the circuit film 210 and serves to protect the sides of the cover window CW.

The third adhesive layer AF3 can be an optically clear adhesive specifically manufactured for optically transparent bonding. Further, the third adhesive layer AF3 can be made of an acrylic resin, a poly(methacrylate) resin, a vinyl resin, a styrene resin, an ester resin, a rubber resin, an epoxy resin, a polyimide resin, a polyamide resin, a phenoxy resin, a polyurethane resin, or the like.

In this case, when the circuit film 210 is bonded in a state in which the polarizing film POL is provided, the circuit film 210 and the polarizing film POL can be disposed so as not to overlap each other.

In this manner, when a separation distance is formed between the circuit film 210 and the polarizing film POL, static electricity from outside can be introduced into the display panel along the surface of the cover window CW and supplied to the data line DL connected to the circuit film 210, thereby causing a line defect or a driving defect.

Such static electricity can be transferred not only to the data line DL, but also to the adjacent signal lines or to the probing pads AP.

In the display device 100 of the present disclosure, after the circuit film 210 is disposed, the upper layer can be disposing so that a portion thereof overlaps the circuit film 210, thereby blocking static electricity flowing in from the outside and reducing defects.

The display device 100 of the present disclosure can include the following multiple-layer structure to prevent static electricity from entering the probing pads AP located on an outside of the circuit film 210 and the signal lines such as the data lines DL connected to the circuit film 210.

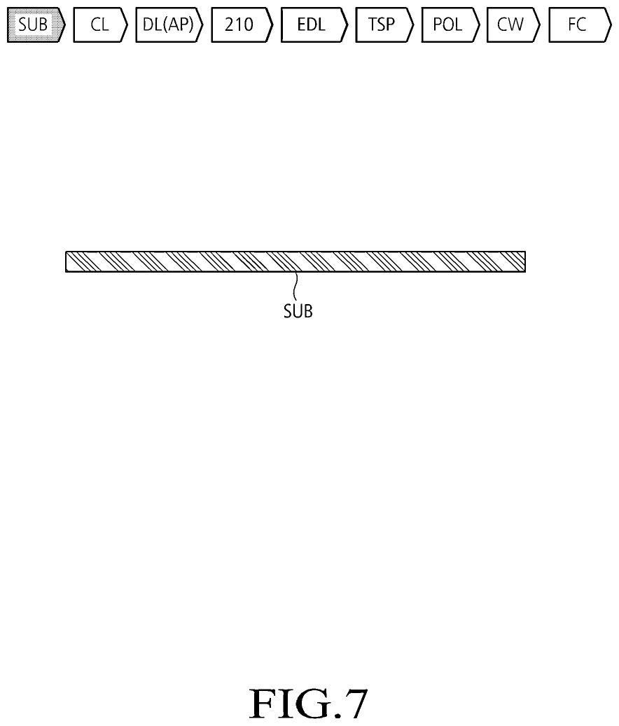

FIGS. 7 to 15 are cross-sectional views sequentially illustrating a process of manufacturing a display device according to embodiments of the present disclosure.

First, the process of manufacturing the display device 100 of the present disclosure includes disposing a substrate SUB, as shown in FIG. 7. The substrate SUB can be made of a transparent material, such as glass.

The substrate SUB can be implemented as a plastic film made of one selected from polyimide (PI), polyethylene naphthalate (PEN), polyethylene terephthalate (PET), other polymers, or a combination thereof.

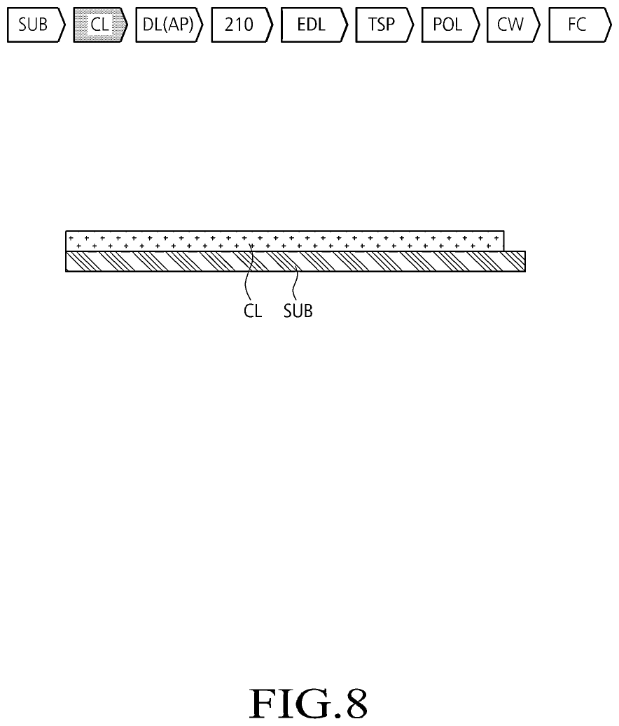

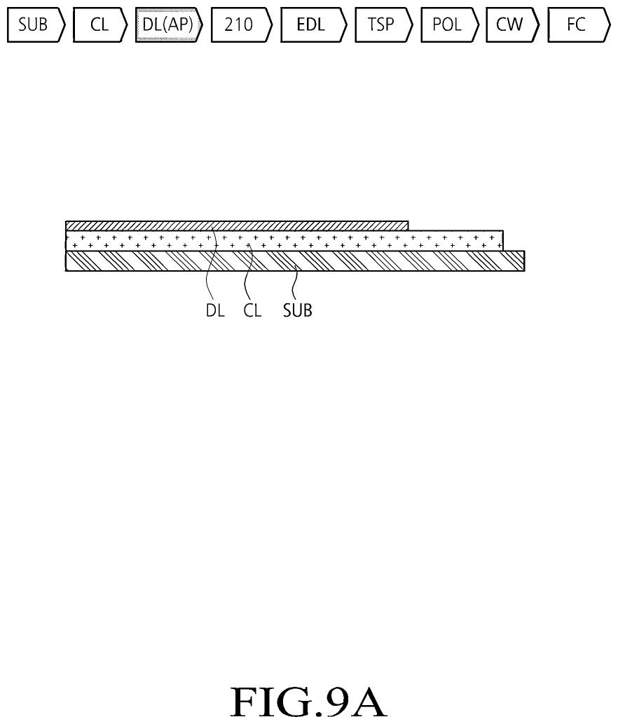

A circuit layer CL including a driving transistor for driving a light-emitting element and a switching transistor can be provided over the substrate SUB, as shown in FIG. 8.

The circuit layer CL can include storage capacitors as well as transistors.

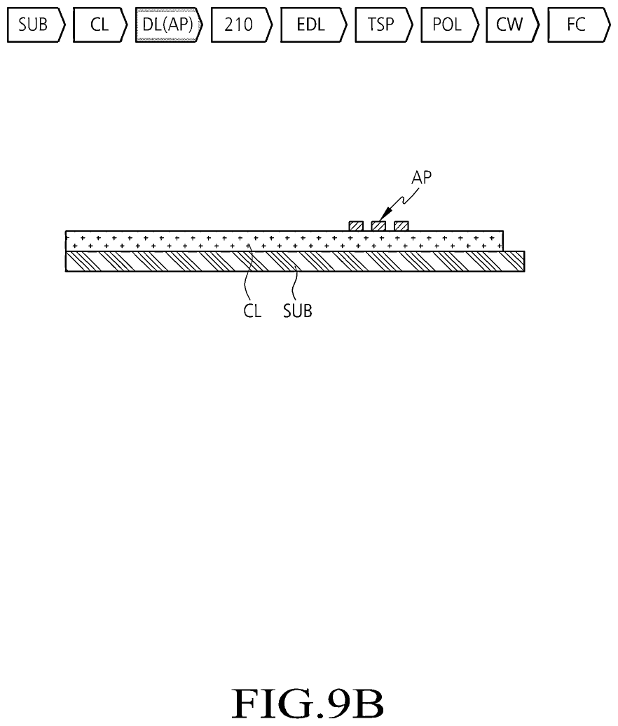

Signal lines can be disposed over the circuit layer CL, as shown in FIG. 9A. The signal lines can include data lines DL through which data voltages are transmitted.

In addition, the signal lines disposed over the circuit layer CL can include gate lines, high-potential voltage lines, low-potential voltage lines, and the like.

FIG. 9A shows a cross-section of a portion in which data lines DL are provided to extend along the circuit film 210.

On the other hand, probing pads AP capable of inspecting for defects in signal lines or film patterns on the substrate SUB by an inspection of a light-emitting operation can be provided on an outside of the circuit film 210, as shown in FIG. 9B.

The data lines DL and the probing pads AP can be formed of the same material on the same plane. In other words, considering that the data lines DL extend along the surface of the circuit film 210 but the probing pads AP are provided on an outside of the circuit film 210, the data lines DL and the probing pads AP can differ only in position in the plane and shape, and can be formed by the same process or of the same material.

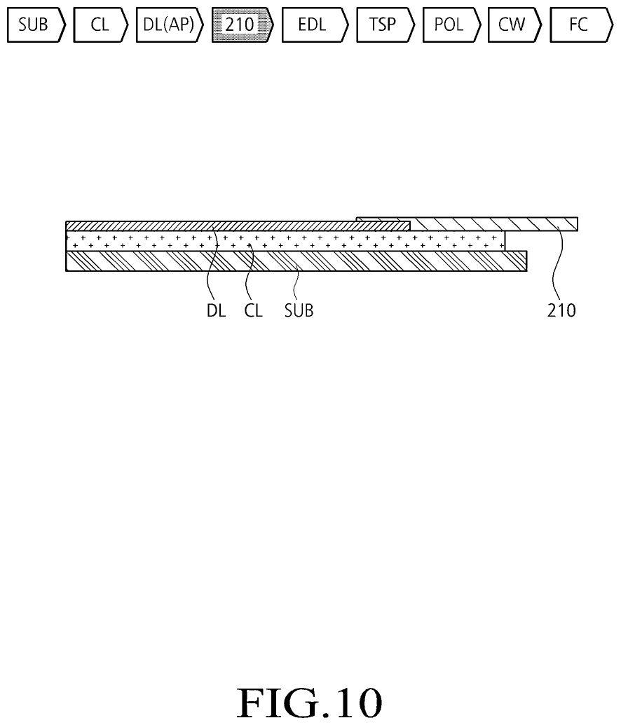

Thereafter, the circuit film 210 is deposited such that data pads located on the bottom of the circuit film 210 are in contact with the data lines DL, as shown in FIG. 10.

Data driving integrated circuits SDIC, touch driving integrated circuits ROIC, or integrated circuits 200 can be mounted over the circuit film 210.

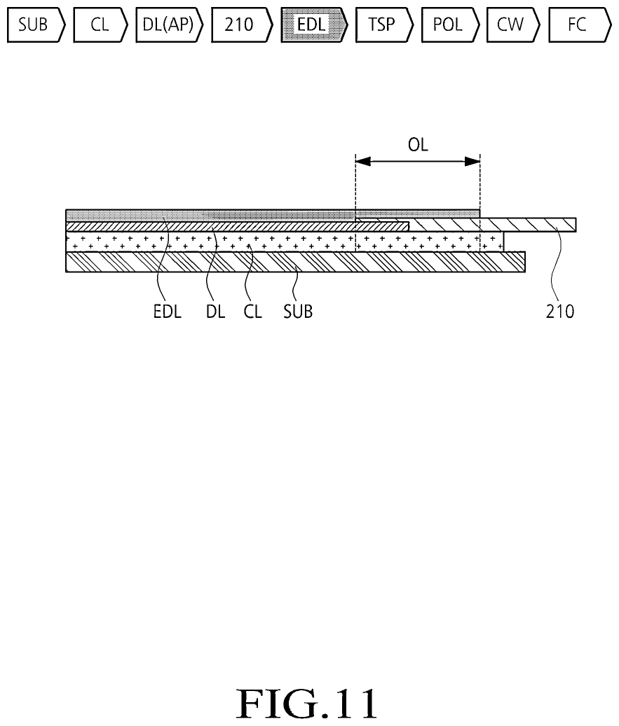

A light-emitting element layer EDL can be formed over the data lines DL and the probing pads AP to cover a portion of the circuit film 210, as shown in FIG. 11.

The light-emitting element layer EDL can include an anode, an emission layer, and a cathode. The emission layer can include a hole injecting layer (HIL), a hole transporting layer (HTL), an emitting material layer (EML), an electron transporting layer (ETL), and an electron injecting layer (EIL).

The light-emitting element layer EDL covers the data lines DL and the probing pads AP. In an overlap area OL, at least a portion of the light-emitting element layer EDL can overlap the circuit film 210 from above.

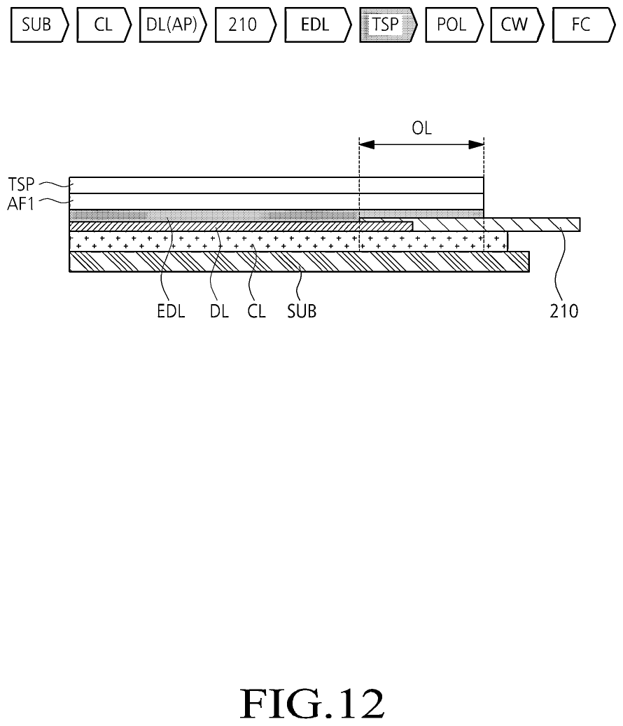

Thereafter, the touchscreen panel TSP is bonded to the light-emitting element layer EDL using a first adhesive layer AF1, as shown in FIG. 12.

When the display device 100 is not provided with a touch function, the touchscreen panel TSP can be omitted.

Similar to the light-emitting element layer EDL, the touchscreen panel TSP can be disposed to cover the data lines DL and the probing pads AP. In the overlap area OL, at least a portion of the touchscreen panel TSP can overlap the circuit film 210 from above.

The first adhesive layer AF1 can be an optically clear adhesive (OCA) manufactured for optically transparent bonding. When the first adhesive layer AF1 is made of an optically clear adhesive, the first adhesive layer AF1 can have hyper elastic properties and can have a low modulus of elasticity to absorb stresses in the display panel 110.

In addition, the first adhesive layer AF1 can have a high strain rate to absorb stress due to bending of the display panel 110.

The first adhesive layer AF1 can be made of an acrylic resin, a poly(methacrylate) resin, a vinyl resin, a styrene resin, an ester resin, a rubber resin, an epoxy resin, a polyimide resin, a polyamide resin, a phenoxy resin, a polyurethane resin, or the like.

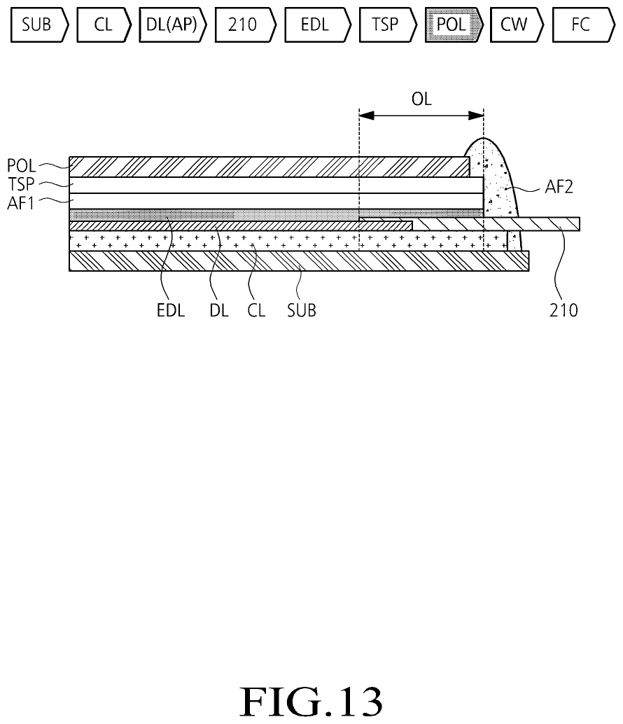

The polarizing film POL is disposed on the touchscreen panel TSP to cover at least a portion of the circuit film 210, as shown in FIG. 13. The overlap area OL of the polarizing film POL and the circuit film 210 can be the same or different from the touchscreen panel TSP and the light-emitting element layer EDL.

However, the polarizing film POL can be desirably formed so as not to extend beyond the substrate SUB thereunder.

After the polarizing film POL is formed, a second adhesive layer AF2 can be supplied to fix sides of the polarizing film POL, the touchscreen panel TSP, the light-emitting element layer EDL, and the circuit layer CL and to protect the same from foreign matter. The second adhesive layer AF2 can be made of a resin.

In this manner, when the polarizing film POL is extended to overlap the circuit film 210, reflection of light entering from the outside can be reduced by the polarizing film POL. The polarizing film POL can also prevent static electricity from entering the data lines DL or the probing pads AP thereunder.

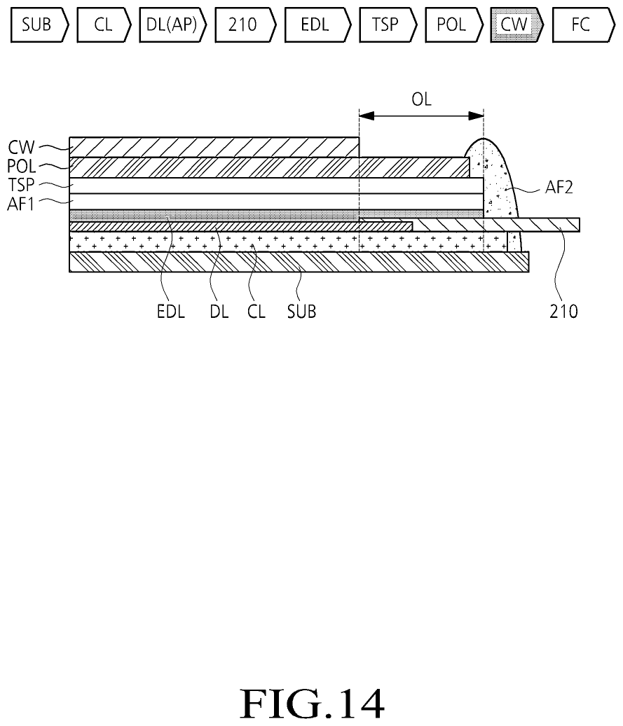

The cover window CW can be disposed over the polarizing film POL, as shown in FIG. 14. The cover window CW can be disposed so as to overlap the circuit film 210, or so as not to overlap the circuit film 210.

The cover window CW can be made of a transparent plastic material, a glass material, or a tempered glass material. In an example, the cover window CW can be a sapphire glass or a Gorilla Glass, or can have a multiple-layer structure thereof. In another example, the cover window CW can include one material selected from polyethylene terephthalate (PET), polycarbonate (PC), polyether sulfone (PES), or polyethylenenaphthalate (PEN). The cover window CW can be made of tempered glass for scratch resistance and transparency.

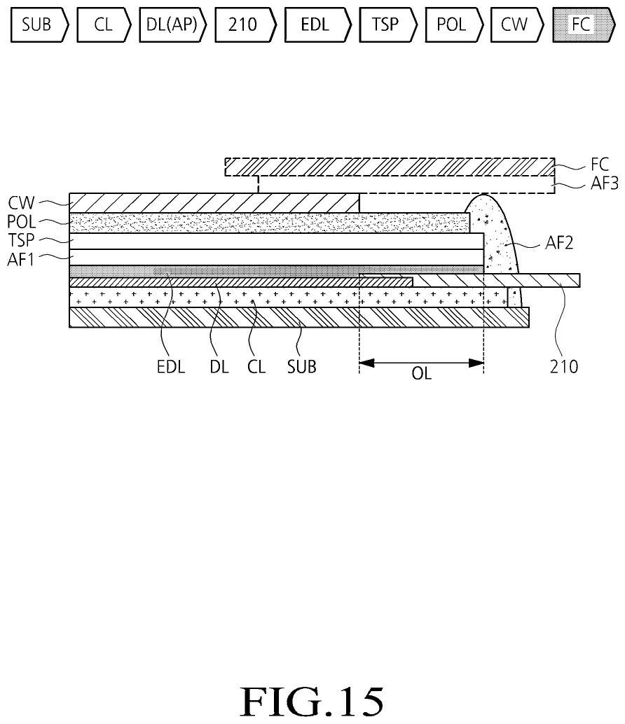

The cover window CW can be bonded to the front cover FC through the third adhesive layer AF3, as shown in FIG. 15. The front cover FC serves to protect the sides of the cover window CW.

The third adhesive layer AF3 can be implemented as an optically clear adhesive specifically manufactured for optically transparent bonding. Further, the third adhesive layer AF3 can be made of an acrylic resin, a poly(methacrylate) resin, a vinyl resin, a styrene resin, an ester resin, a rubber resin, an epoxy resin, a polyimide resin, a polyamide resin, a phenoxy resin, a polyurethane resin, or the like.

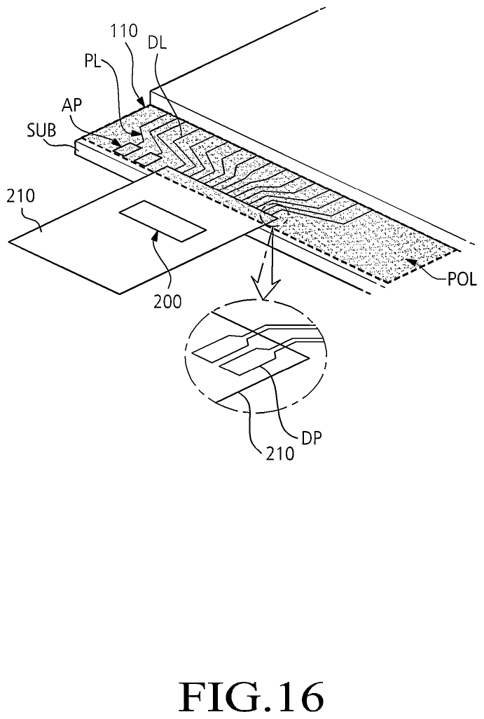

FIG. 16 illustrates an arrangement of a polarizing film in a non-display area of the display device according to embodiments of the present disclosure.

Referring to FIG. 16, in the display device 100 according to embodiments, probing pads AP to be contacted by a needle of an automatic probe inspection device and inspection lines PL connected to the probing pads AP are provided on a substrate SUB to enable the automatic probe inspection.

The probing pads AP can be disposed on an outside of the substrate SUB, and the data pads DP to which the data lines DL are connected can be disposed on an edge of the circuit film 210.

Data lines DL supplying data voltages to the display panel 110 can be connected to the integrated circuit 200 through data pads DP provided on an edge of the circuit film 210.

The inspection lines PL connected to the probing pads AP can extend along the non-display area of the display panel 110 and connected to switching elements located outside the display area.

In this manner, in the display device 100 of the present disclosure, in a state in which the circuit film 210 is bonded to the substrate SUB, the polarizing film POL is disposed over the circuit film 210 so as to overlap at least a portion of the circuit film 210.

In this manner, in the display device 100 of the present disclosure, after the circuit film 210 is bonded, the polarizing film POL can be disposed to overlap at least a portion of the circuit film 210 from above so that the polarizing film POL can block light or static electricity introduced from the outside. As a result, line defects or driving defects in the data lines DL or the probing pads AP provided on the substrate SUB can be prevented.

The polarizing film can be a synthetic resin film including at least one selected from a group consisting of polyether sulfone (PES), polyacrylate, polyether imide (PEI), polyethylene napthalate (PEN), polyethylene terephthalate (PET), polyphenylene sulfide (PPS), polyarylate (PA), polyimide (PI), and polycarbonate (PC).

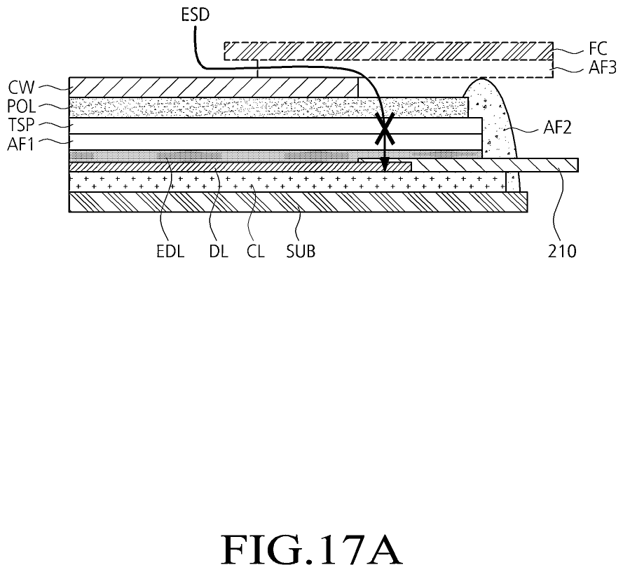

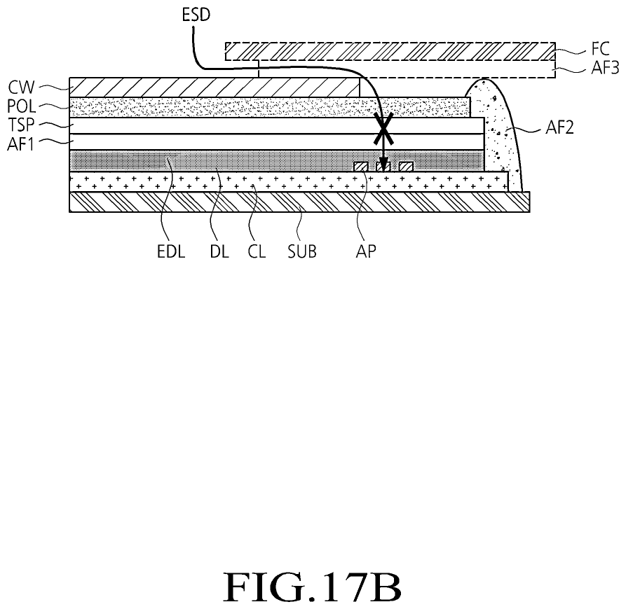

FIGS. 17A and 17B are cross-sectional views illustrating an example in which the polarizing film blocks static electricity introduced from the outside.

Referring to FIGS. 17A and 17B, as described above, when the circuit film 210 is bonded to the substrate SUB of the display panel and then the upper polarizing film POL is formed over the circuit film 210 to overlap at least a portion of the circuit film 210, the polarizing film POL can reduce the entry of external light or static electricity.

As a result, static electricity flowing into the data lines DL or the probing pads AP along the surface of the cover window CW can be blocked, which has the effect of reducing the problem of line failures or poor operation.

The above-described embodiments of the present disclosure are briefly reviewed as follows.

A display device according to various aspects of the present disclosure can include a display panel including an arrangement of a plurality of subpixels; and at least one driving circuit driving the display panel, wherein the display panel includes: a substrate; a circuit layer provided on the substrate; signal lines disposed over the circuit layer and electrically connected to a circuit film on which the driving circuit is mounted; a light-emitting element layer disposed over the signal lines and disposed to overlap at least a portion of the circuit film; a polarizing film provided over the light-emitting element layer and disposed to overlap at least a portion of the circuit film; an adhesive layer covering sides of the polarizing film, the light-emitting element layer, and the circuit layer; and a cover window provided over the polarizing film.

The signal lines can be data lines through which data voltages are supplied.

Data pads to which the data lines are connected can be disposed on an edge of the circuit film.

The light-emitting element layer and the polarizing film can be disposed to cover the signal lines.

The display panel can further include probing pads disposed on the circuit layer and located on an outside of the circuit film.

The light-emitting element layer and the polarizing film can be disposed to cover the probing pads.

The display panel can further include a touchscreen panel bonded between the light-emitting element layer and the polarizing film.

The touchscreen panel can be disposed to cover the signal lines.

The cover window can be disposed so that the cover window does not overlap the circuit film.

The display device can further include a front cover bonded to a top portion of the cover window and disposed to cover the circuit film.

The polarizing film can be a synthetic resin film including at least one selected from a group consisting of polyether sulfone (PES), polyacrylate, polyether imide (PEI), polyethylene napthalate (PEN), polyethylene terephthalate (PET), polyphenylene sulfide (PPS), polyarylate (PA), polyimide (PI), and polycarbonate (PC).

In addition, a display panel according to the present disclosure can include a substrate; a circuit layer provided on the substrate; signal lines disposed over the circuit layer and electrically connected to a circuit film on which a driving circuit is mounted; a light-emitting element layer disposed over the signal lines and disposed to overlap at least a portion of the circuit film; a polarizing film provided over the light-emitting element layer and disposed to overlap at least a portion of the circuit film; an adhesive layer covering sides of the polarizing film, the light-emitting element layer, and the circuit layer; and a cover window provided over the polarizing film.

The above description has been presented to enable any person skilled in the art to make and use the technical idea of the present invention, and has been provided in the context of a particular application and its requirements. Various modifications, additions and substitutions to the described embodiments will be readily apparent to those skilled in the art, and the general principles defined herein can be supplied to other embodiments and applications without departing from the spirit and scope of the present invention. The above description and the accompanying drawings provide an example of the technical idea of the present invention for illustrative purposes only. For example, the disclosed embodiments are intended to illustrate the scope of the technical idea of the present invention.

What is claimed is:

1. A display device comprising:
a display panel including a plurality of subpixels; and
at least one driving circuit configured to drive the display panel,
wherein the display panel includes:
a substrate;
a circuit layer disposed on the substrate;
signal lines disposed on the circuit layer and electrically connected to a circuit film on which the driving circuit is mounted;
a light-emitting element layer disposed on the signal lines and disposed to overlap at least a portion of the circuit film;
a polarizing film disposed on the light-emitting element layer and disposed to overlap at least a portion of the circuit film;
an adhesive layer covering sides of the polarizing film, the light-emitting element layer, and the circuit layer; and
a cover window disposed on the polarizing film.

2. The display device of claim 1, wherein the signal lines include data lines through which data voltages are supplied.

3. The display device of claim 2, wherein data pads to which the data lines are connected are disposed on an edge portion of the circuit film.

4. The display device of claim 1, wherein the light-emitting element layer and the polarizing film are disposed to cover the signal lines.

5. The display device of claim 1, wherein the display panel further comprises probing pads disposed on the circuit layer and disposed on an outside of the circuit film.

6. The display device of claim 5, wherein the light-emitting element layer and the polarizing film are disposed to cover the probing pads.

7. The display device of claim 1, wherein the display panel further comprises a touchscreen panel bonded between the light-emitting element layer and the polarizing film.

8. The display device of claim 7, wherein the touchscreen panel is disposed to cover the signal lines.

9. The display device of claim 1, wherein the cover window is disposed so that the cover window does not overlap the circuit film.

10. The display device of claim 1, further comprising a front cover bonded to a top portion of the cover window and disposed to cover the circuit film.

11. The display device of claim 1, wherein the polarizing film is a synthetic resin film comprising at least one selected from a group consisting of polyether sulfone (PES), polyacrylate, polyether imide (PEI), polyethylene napthalate (PEN), polyethylene terephthalate (PET), polyphenylene sulfide (PPS), polyarylate (PA), polyimide (PI), and polycarbonate (PC).

12. A display panel comprising:
a circuit layer disposed on a substrate;
signal lines disposed on the circuit layer and electrically connected to a circuit film on which a driving circuit is mounted;
a light-emitting element layer disposed on the signal lines and disposed to overlap at least a portion of the circuit film;
a polarizing film disposed on the light-emitting element layer and disposed to overlap at least a portion of the circuit film;
an adhesive layer covering sides of the polarizing film, the light-emitting element layer, and the circuit layer; and
a cover window disposed on the polarizing film.

13. The display panel of claim 12, wherein the signal lines are data lines through which data voltages are supplied.

14. The display panel of claim 13, wherein data pads to which the data lines are connected are disposed on an edge portion of the circuit film.

15. The display panel of claim 12, wherein the light-emitting element layer and the polarizing film are disposed to cover the signal lines.

16. The display panel of claim 12, further comprising probing pads disposed on the circuit layer and disposed on an outside of the circuit film.

17. The display panel of claim 16, wherein the light-emitting element layer and the polarizing film are disposed to cover the probing pads.

18. The display panel of claim 12, further comprising a touchscreen panel bonded between the light-emitting element layer and the polarizing film.

19. The display panel of claim 18, wherein the touchscreen panel is disposed to cover the signal lines.

20. The display panel of claim 12, wherein the cover window is disposed so that the cover window does not overlap the circuit film.

21. The display panel of claim 12, wherein the polarizing film is a synthetic resin film comprising at least one selected from a group consisting of polyether sulfone (PES), polyacrylate, polyether imide (PEI), polyethylene napthalate (PEN), polyethylene terephthalate (PET), polyphenylene sulfide (PPS), polyarylate (PA), polyimide (PI), and polycarbonate (PC).
